(19) United States
(12) Patent Application Publication
(10) Pub. No.: US 2021/0335440 A1
(43) Pub. Date: Oct. 28, 2021

(54) MEMORY TEST ENGINE WITH FULLY PROGRAMMABLE PATTERNS

(71) Applicant: FLC Technology Group, Inc., Santa Clara, CA (US)

(72) Inventors: Jiapeng Guo, Santa Clara, CA (US); Hunglin Hsu, Cupertino, CA (US); Cheng Chung Wang, Santa Clara, CA (US); Xin Song, Santa Clara, CA (US); Xi Zhu, San Jose, CA (US); Sehat Sutardja, Las Vegas, NV (US)

(21) Appl. No.: 17/243,304

(22) Filed: Apr. 28, 2021

Related U.S. Application Data
(60) Provisional application No. 63/016,900, filed on Apr. 28, 2020.

(51) Int. Cl. G11C 29/36; G11C 29/16; G11C 29/44

(52) U.S. Cl. CPC G11C 29/36; G11C 29/16; G11C 2029/4402; G11C 2029/3602; G11C 29/44

(57) ABSTRACT

A memory test system including a memory storing non-transitory machine executable instructions configured to generate test patterns. A processor or state machine is configured to execute the machine executable instructions to generate the test patterns. A memory controller receives the test patterns, writes the generated test patterns to a memory being tested, and reads the test patterns from the memory being tested to create read test patterns. A comparator or controller is configured to compare the generated test patterns to the read test patterns and responsive to differences between the generated test patterns and the read test patterns, generate a memory read error. Pass/fail registers may store data and a memory address associated with the memory read error. The test patterns can be stored for a period of time before being read to test the ability of the memory being tested to store the test pattern.

### 1. FIELD OF THE INVENTION

The innovation relates to memory testing and in particular to a method and apparatus for functional memory tests using programmable test patterns.

### 2. RELATED ART

Advances and developments in the semiconductor industry and fabrication technology provide technology to integrate an entire system on a single chip or die. These system on chip (SOC) designs reduce costs, space, and PCB layout complexity. To further save space and increase speed, memory elements (DRAM) are integrated into the core of the chip in the SOC device. As a result, the communication delay from the core of the SOC, such as from an on-chip processor, to the DRAM is reduced by reducing interface and interconnection topology.

For SOC designs which integrate the memory elements on the SOC device, the need for reliability of the DRAM device increases. If the DRAM that is part of a SOC device is defective or becomes non-operational after being placed in service, it is often not repairable or replaceable. Because the memory is integrated with the SOC, the memory cannot be easily replaced as could occur if the memory were configured in a separate memory module. As a result, the entire SOC is rendered non-functional and must be replaced. This leads to significant system down time and greater lifetime costs as a result for a replacement.

Another concern is that the failure of memory, that is part of a SOC device, will not only lead to a failure of the system, but also cause further systems or an associated device to fail. For example, in the case of a mobile communication device, such as a smartphone or tablet, if the SOC fails, often the entire mobile communication device must be discarded.

One proposed test function is a built-in self-test, commonly referred to as a BIST. A BIST operation is configured to test memory, but this type of testing suffers from several drawbacks. One drawback is that it only tests a limited set of memory aspects. For example, prior art BIST circuits are a static, hardwired test mechanism configured to only test connectivity, such as open circuits and shorted conductors. Thus, a BIST operation is fixed as a single test routine and only limited set of structural connections are tested. In addition, prior art BIST operations were static, being enabled in hardwired circuitry. This prevented the BIST operation from being changed or updated over time, which results in an inability of the BIST hardware to accommodate new test parameters.

Another proposed solution is an external memory tester that connects to a SOC device. However, external memory test systems suffer from several drawbacks. One such drawback was that prior art external memory test systems are expensive to purchase and operate. The external memory test system is a separate item of test equipment and requires a skilled technician to operate. Further, prior art external memory test systems are time consuming to operate and thus slow production throughput. To test a memory, the external memory test system must be physically connected to the part under test by a technician, the result analyzed, and then the part under test must be disconnected from the test equipment. These time-consuming, labor-intensive operations reduce throughput.

As a result, there is a need for a cost effective, dynamic, functional memory test. The innovation disclosed herein meets that need and provides additional benefits.

### SUMMARY

To overcome the drawbacks of the prior art, a system for testing memory is disclosed. In one embodiment, this system includes a first memory storing non-transitory machine executable instructions configured to, when executed, generate test patterns. A processor is provided that is in communication with the memory. The processor is configured to execute the machine executable instructions to generate the test patterns. A memory controller is configured to receive the test patterns, write the generated test patterns to the first memory or a second memory, and read the test patterns from the first memory or the second memory to create read test patterns. A controller is configured to compare the generated test patterns to the read test patterns and responsive to differences between the generated test patterns and the read test patterns, generate a memory read error.

This system may also include pass/fail registers configured to store data regarding the memory read error. In one embodiment, the test patterns are stored for a first time period before being read to test the first memory's or the second memory's ability to store the test pattern for the first time period. It is contemplated that the system for testing memory may be part of a system on chip device. The second memory may be DRAM. In one embodiment, the machine executable instructions comprise micro-code and the processor comprises a micro-code engine.

Also disclosed is a method of testing memory of a system that includes memory. In one embodiment this method comprises executing machine executable instructions to generate a test pattern. The machine executable instructions are stored in a non-transitory state in the system. Then, the test pattern is written to the memory as a written test pattern to test the memory's ability to write the test pattern and have the test pattern read from memory. Then, reading the test pattern from the memory as a read test pattern and comparing the written test pattern to the read test pattern. Responsive to the comparing determining that the written test pattern matches the read test pattern, designating a memory pass status, or responsive to the comparing determining that the written test pattern does not matches the read test pattern, designating a memory fail status.

In one embodiment, this method may further comprise delaying the reading the test pattern after writing the test pattern for a time period to test the memory's ability to store data. It is contemplated that the machine executable instructions which create the test pattern are stored in a different memory than the memory being tested. The step of comparing may include tracking a memory location associated with data that forms the read test pattern to thereby identify memory locations at which the written test pattern does not matches the read test pattern. The writing, reading and comparing may occur repeatedly to test the entire memory or to repeatedly test a same memory location to identify intermittent errors. The memory being tested may comprise DRAM. This method of operation may also include logging and storing the results of the comparison, or other analysis, of the written test data and the read test data to a pass/fail registers. In one embodiment, in response to a memory fail status, the system takes protective action that includes one or more of the following: repair, masking, replacement, or removal from a memory map.

Also disclosed is a memory test system comprising a controller configured to initiate testing of the memory, a test pattern generator configured to generate test patterns, a memory controller configured to write test patterns to memory and read the written test patterns from memory, and a comparator configured to compare the written test pattern to the read test pattern to identify memory locations that result in memory errors.

In one embodiment, the test pattern generator is a processor executing micro-code such that the micro code configured to generate the test patterns. The micro-code may be written to a memory assessable by the processor and may be re-written by a user of the memory test system to thereby generate different test patterns. It is contemplated that the system may further comprise registers configured to store the results of the comparing. In one configuration, the controller is configured to introduce a delay between the writing of the test pattern and the reading of the test pattern. In one embodiment, the system further comprises a memory storing a non-transitory test pattern and the test pattern generator is configured retrieve the test pattern from the memory.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 is a block diagram illustrating an example environment of use of the DRAM test engine.

FIG. 2 is a block diagram illustrating an example embodiment of the DRAM test engine.

FIG. 3 is an operational flow diagram of an example method of operation of the DRAM test engine.

### DETAILED DESCRIPTION

To extend the functionality of memory operations that is integrated with a SOC device and thus the entire SOC device, a memory test engine is proposed to be configured with the SOC or external to the SOC. The memory test engine is referred to herein as a DRAM Test Engine (DTE) that is configured to test the DRAM functionality and accurately identify failed memory cells or memory cells that are on a path to failure. This information can be used to extend DRAM lifetime, protect system operation, eliminate the need to replace expensive electronics prior to a planned end of life, or enable planned replacement.

A DTE overcomes the prior art drawbacks associated with embedded memories without the need for an expensive external memory tester. The disclosed system is a fully programmable turnkey solution allowing users to write code in high level programming languages, which are then compiled to microcode. The microcode, when executed, generates test patterns which functionally test the memory, such as but not limited to, DRAM. This enables a high speed, high code-density test process which provides a general purpose or purpose specific test suite for current and future memory devices. The disclosed system and method provide a fully programmable microcode solution for DRAM testing allowing new testing patterns and devices to be supported by loading the new microcode to the internal memory of the test engine. The microcode is executed by the DTE and can later be converted to DRAM transactions, such as memory write and read operations.

In one embodiment DTE comprises hardware and associated software that generates and writes test patterns to DRAM devices. The test patterns are then read from the DRAM and compared to the original patterns to check data integrity and functionality and identify the location of failed or failing memory cells.

Upon locating one or more weak/broken cells or pages in the DRAM, the DTE updates the memory controllers so that the memory controller may mask out or otherwise account for the failed or failing cells and take remedial action to the extent possible.

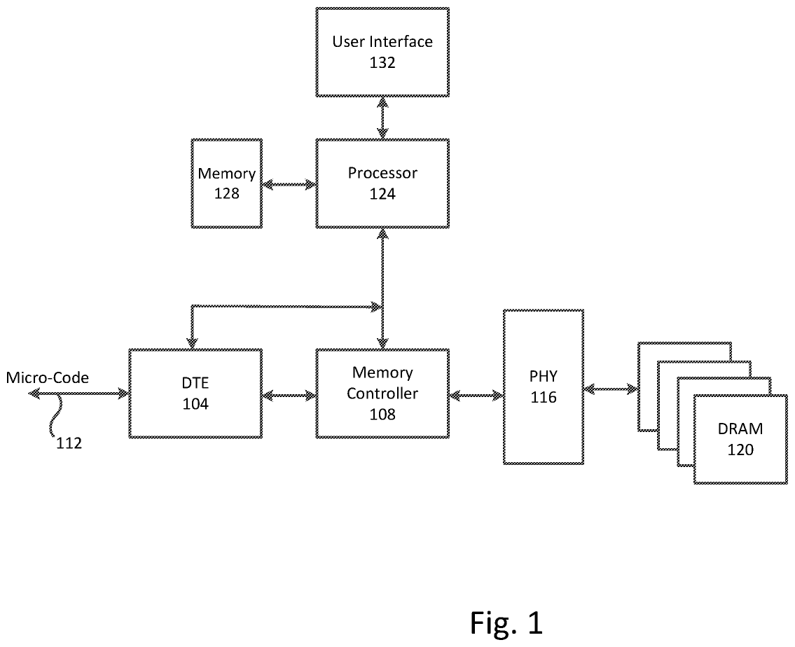

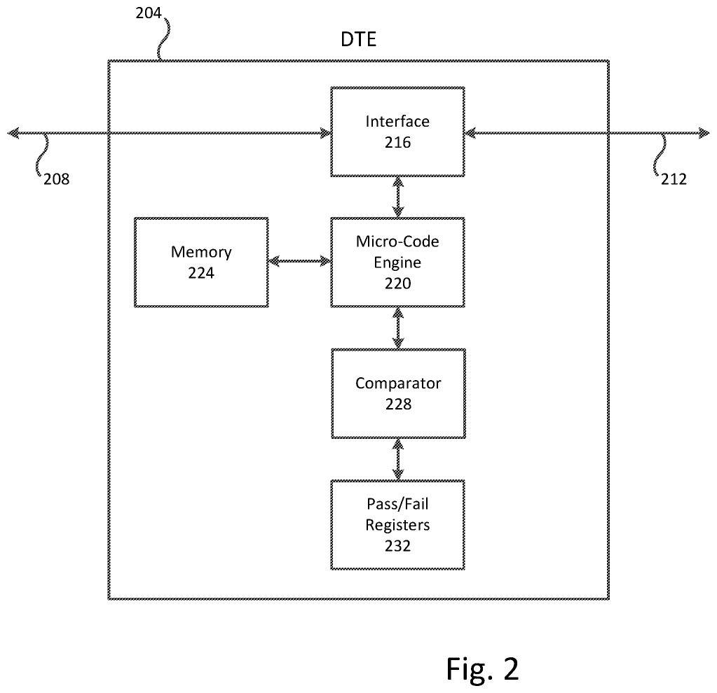

FIG. 1 is a block diagram illustrating an example environment of use of the DRAM test engine (DTE). This is but one possible environment of use and it is contemplated that the DTE disclosed herein may be utilized in other environments and configurations. In this embodiment, the DTE 104 connects to a memory controller 108. The DTE is described in greater detail in FIG. 2. The memory controller 108 is configured and operates as is known in the prior art. The DTE receives an input 112 of microcode, such as at the time of manufacture or thereafter.

The microcode may also be provided to the DTE 104 via a processor 124. The processor 124 may be any type processor, microcontroller, or equivalent device. The memory 128 may be any type memory, such as but not limited to ROM. The microcode may be stored on the memory 128 that is accessible by the processor 124. A user interface 132 is provided to provide means for a user to load microcode onto the memory 128 and control transfer of the microcode to the DTE 104. Once stored on the memory 128 the microcode may be transferred from ROM memory 128, such as using drivers, to the DTE 104 via the processor 124 as shown or via some other path (not shown). The microcode may be stored in an addressable space the ROM memory 128. New microcode (or uncompiled code) can be loaded into the addressable space of the ROM memory 128 using the drivers, and then transferred to the DTE to update or change the test pattern.

The output of the memory controller 108 connects to a physical layer (PHY) 116, which in turn connects to system memory, in this embodiment DRAM 120. The PHY 116 interfaces the memory controller 108 and the DRAM 116 while the DRAM stores data and software instructions during system operation. The configuration and operation of the PHY 116 and the DRAM 120 is known in the art and as such is not described in detail herein.

In operation, the microcode, which is discussed below in greater detail, is executed on the DTE 104 to generate a test pattern. The generated test pattern may be stored in the DTE for future comparison and is also provided to the memory controller 108. The memory controller 108 processes the test pattern into a format suitable for a burst write operation to the DRAM 120 via the PHY 116. As a result, the test pattern is stored in the DRAM 120. The test pattern may be any size or pattern and its write pattern may be controlled by the DTE 104 or the memory controller 108. Overtime, selected cells or all cells of the DRAM 120 are filled with the test pattern. This may occur once or repeat any number of times.

After a pre-determined amount of time that the test pattern is stored in the DRAM 120, a read operation occurs such that the memory controller reads the test pattern from the DRAM. The wait state leaving the test pattern in memory may occur to verify that DRAM can accurately store data over time. In one embodiment, one burst of test pattern is written to the DRAM at a time, and then read from the DRAM. Once read from DRAM 120, the read test pattern is provided to the DTE 104 which compares the read test pattern to the original test pattern which was previously stored in the DTE.

The comparison reveals differences between the written test pattern and the read test pattern, thereby revealing memory cells which may be non-functional or on a path to failure. The process may be repeated several times for the same memory cells to reveal memory cells which are intermittently or periodically faulty. The memory cells of the DRAM 120 that are detected to be at or near failure are tracked and reported to the memory controller.

### MicroCode

The microcode is machine executable instructions which are stored in the DTE 104 and executable by a DTE micro-code engine, processor or micro-controller to generate test patterns. The microcode may be generated in a number of ways. One possible method to create the microcode is to write a software routine in a high-level programming language such as C or any C language derivative. Once the software routine is coded in a high-level programming language, it may be processed by an open source or custom compiler (along with scripts) to generate the microcode. The instruction set of the microcode is customized including all necessary, instructions required to create the test patterns. It is contemplated that the instruction set is much smaller than a general-purpose instruction set, such as x86. Once the microcode is compiled, it may then be stored in the DTE 104 at the time of manufacture or at a later time such as with a driver accessing the memory 128 and processor 124 combination, or any other suitable path into the DTE.

### Test Patterns

The test patterns may comprise any type pattern of digital data configured to test the functionality of the DRAM. In general, the test patterns are configured to utilize and stress the bit storage cells and/or hardware in the DRAM. Example test patterns are available from APMemory located in Zhubei City, Taiwan (www.APMemory.com). Example test patterns include X-fast March 6N and X-fast scan 4N, and numerous other patterns may be used or developed in the future.

FIG. 2 is a block diagram illustrating an example embodiment of the DRAM test engine. The DTE shown in FIG. 2 is but one possible configuration and arrangement and as such it is contemplated that other configurations are possible. In this example embodiment, the DRAM test engine (DTE) 204 includes an input/output path 208 configured to receive the microcode and provide test result or other type data back to a user upon request, such as via the user interface 132 shown in FIG. 1. Also part of the DTE 204 is a memory I/O path 212 configured to send memory write and read requests to the memory controller as well as send the test pattern to the memory controller and receive the test pattern that was read from the DRAM from the memory controller.

The DTE 204 further includes a micro-code engine 220 configured to oversee operation of the DTE by executing machine readable code, referred to herein as microcode that is stored in the memory 224 as non-transitory instructions. The micro-code engine 220 may comprise any device capable of executing the micro-code, such as but not limited to a microcontroller, processor, or general or special purpose engine configured to execute micro-code. As discussed herein, the micro-code engine 220 reads the microcode (machine executable instructions) from memory and executes the microcode to generate the test pattern. The micro-code engine 220 may also be referred to as a test engine or test processor, test logic, or test controller. In one embodiment, the DTE memory 224 comprises SRAM, but in other embodiments any type of memory may be used that is capable of storing the microcode. In other embodiments, a finite state machine may be used to generate the test patterns or execute the micro-code. In one configuration the state machine is custom configured to operate with the micro-code develop for the state machine. In one embodiment the microcode generates the test patterns and the test patterns are directly written to DRAM. In one embodiment, the micro-code engine generates the test pattern, and the generated test pattern is stored and memory, and then written to the DRAM.

It is also contemplated that test patterns may be loaded into the memory 224 via the interface 216 and stored for future use. One or more different test patterns and stored in the memory 224 may be recalled and sent to the memory. The same test pattern may repeatedly written to memory and read. Test patterns loaded into memory 224 and stored there may reduce computational complexity of the system and dependent on the size of the memory 224 any number of or complexity of test matters may be stored in the memory.

An interface 216 coordinates receipt and installation of the microcode in the memory 224 and also to provide data regarding the memory test results to a user or to the system processor 124 of FIG. 1. The interface may also coordinate input and output of the test pattern over the memory I/O 212. Also part of the DTE 204 is one or more comparators 228 configured to compare the generated test pattern that is written to the DRAM (written test data) to the test pattern that is read from the DRAM (read test data), after storage in the DRAM to determine if the written test data matches the test pattern read from the DRAM. Inconsistences or differences between the written test data and the read test data may reveal failed or failing memory cells in the DRAM. In other embodiments, devices other than a comparator may be used such as a software based comparison or any other element(s) which may be compared in relation to the written test data and the read test data.

As a benefit over the prior art, the type of testing that occurs using the system and method disclosed herein reveals more information regarding the memory than the prior art BIST operation. The writing, reading and comparison using the test patterns determines the functionality of the memory by generating real-time, live write and read requests, transactions, and commands that test all aspects of memory write operation, memory store operations, and memory read operations, including the memory controller and PHY operation. This verifies that the DRAM and associated systems are functioning as intended and is thus a significant advance over the prior art. Examples of the type of functionality testing and/or commands that may occur include but are not limited to the following: activate, pre-charge, and/or refresh. Prior art BIST tests were hardwired and as such were not open to the public and did not have the ability to dynamically adapt to new test, test patterns, and memory types. Likewise, the test performed by prior art BIST tests only tested a limited set of connectivity, and not memory functionality.

Pass/Fail registers 232 are provided to log and store the results of the comparison, or other analysis, of the written test data and the read test data. These registers 232 may be arranged to correspond to or identify the DRAM memory cells such that the failed or failing memory cells may be identified and the faults (faulty memory cells) reported to the memory controller. In one embodiment, when a test pattern is sent to the DRAM 120, the address to which the test pattern is to be written is also provided. The test pattern and associated memory address may be stored in the register or any other location. When the test pattern is read from DRAM, the memory address from which the test pattern was read is also associated with the read test pattern. By associating the DRAM memory address with the written and read test patterns, the faulty memory addresses can be accurately identified during the comparison of the written data to the read data. In one embodiment, the writing to memory, reading from memory, and comparison may operate in a loop or repetitive pattern to thereby test the entire memory one or more times, or portions of the memory one or more times.

As is understood, the memory controller can be configured to take protective action in response to failed or failing memory cells, such as by repair, masking, replacement, or removal from the memory map. Although shown as pass/fail registers 232, it is contemplated that other devices or systems may be used to track and record the results of the comparison between the written test data and the read test data to track and report which memory cells have failed or are failing. In addition, the results of the comparison may also be provided via the interface 216 to the processor 124 of FIG. 1 for reporting to a user or other systems. For example, in systems critical to life or life support systems, functional memory is imperative, and any failures may necessitate system replacement or repair.

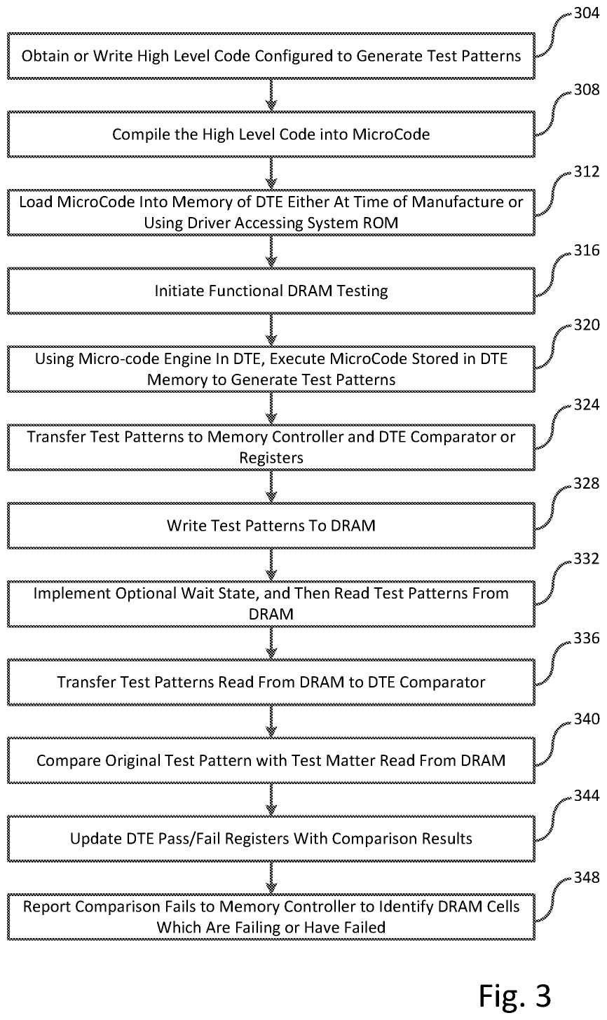

FIG. 3 is an operational flow diagram of an example method of operation of the DRAM test engine. This is but one possible method of operation and it is contemplated that other methods of operation may exist without departing from the scope of this innovation. At a step 304 high level code is written or obtained. The high-level code is compiled into microcode, and when executed generates the test patterns. The microcode may be configured to generate any type of test pattern and during operation more than one type of test pattern may be generated and written and read from memory.

At a step 308, a compiler compiles the high level into microcode. Microcode may comprise a layer or group of small instruction sets. The microcode performs short, control-level register operations, including multiple, micro instructions, each of which performs one or more micro operations to generate the test pattern. Also referenced herein as microcode, any type software code executing on a micro-code engine, microcontroller or processor may be used to generate the test patterns. Any type of programming language and compiler may be used to generate the microcode.

At a step 312, the microcode is loaded in the memory of the DTE either at the time of manufacture or later, such as by using a driver. The driver may receive or access the microcode from a user supplied source (network, USB connected memory, other user memory, or disk) or from microcode stored in system ROM.

At a step 316, the DTE initiates functional testing of the DRAM. This occurs at step 320 with the micro-code engine executing the microcode stored in the DTE memory to generate the test patterns. The microcode acts as a pattern generator. At a step 324 the DTE transfers the test patterns to the memory controller as a write request to the DRAM as well as to the DTE comparator and/or registers. This occurs as would be typical for a request to write data to memory. Then at a step 328, the test patterns are written to the DRAM.

At a step 332, after an optional wait state to let the test pattern reside in memory for a period of time, the test patterns are read from the DRAM. At a step 336 the test pattern read from the DRAM is provided to the DTE comparator. At a step 340 the comparator compares the original test pattern from the DTE to the test pattern just read from the DRAM to determine if differences exist between the two data sets. If differences or faulty data are found, at step 344 the pass/fail registers are updated to reflect the comparison results, such as from which memory cells the faulty data was read. In one embodiment, the DTE will check the correctness of the data and interrupt the device driver if there is an error. However, for small size failures, the DTE or memory controller may call a shadow memory function to replace the DRAM area with registers in the DTE system.

At a step 348 the DTE reports the comparison faults and faulty memory cell locations, if any exist, to the memory controller for appropriate action by the memory controller. This allows the memory controller to remove from service, repair or other account for the memory cells which are failing, or which have failed.

Other systems, methods, features, and advantages of the invention will be or will become apparent to one with skill in the art upon examination of the following figures and detailed description. It is intended that all such additional systems, methods, features, and advantages be included within this description, be within the scope of the invention, and be protected by the accompanying claims.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement. -cm What is claimed is:

1. A system for testing memory comprising:
a first memory storing non-transitory machine executable instructions configured to, when executed, generate test patterns;
a processor, in communication with the memory, the processor configured to execute the machine executable instructions to generate the test patterns;
a memory controller configured to:
receive the generated test patterns;
write the generated test patterns to a second memory as stored test patterns;
read the stored test patterns from the second memory as read test patterns;
a comparator configured to:
compare the generated test patterns to the read test patterns;
responsive to differences between the generated test patterns and the read test patterns, generate a memory read error.

2. The system of claim 1 further comprising pass/fail registers configured to store addresses of the second memory at which memory read errors occur.

3. The system of claim 1 wherein the test patterns written to the second memory as stored test patterns are stored for a time period before being read to test the second memory's ability to store the stored test pattern for the time period.

4. The system of claim 1 wherein the system for testing memory is part of a system on chip device.

5. The system of claim 1 wherein the second memory comprises DRAM and the processor comprises a state machine.

6. The system of claim 1 wherein the machine executable instructions comprise micro-code and the processor comprises a micro-code engine.

7. A method of testing memory associated with a system comprising:
executing machine executable instructions to generate a test pattern, the machine executable instructions stored in a non-transitory state;
writing the generated test pattern to the memory as a written test pattern to test the memory's ability to write the test pattern and have the test pattern read from memory;
reading the test pattern from the memory as a read test pattern;
comparing the written test pattern to the read test pattern;
responsive to the comparing determining that the written test pattern matches the read test pattern, designating a memory pass status; and
responsive to the comparing determining that the written test pattern does not match the read test pattern, designating a memory fail status.

8. The method of claim 7 further comprising delaying the reading of the test pattern after writing the test pattern for a time period to test the memory's ability to store data.

9. The method of claim 7 wherein the machine executable instructions which create the test pattern are stored in a different memory than the memory being tested.

10. The method of claim 7 wherein the comparing includes tracking a memory location associated with data that forms the read test pattern to thereby identify memory locations at which the written test pattern does not match the read test pattern.

11. The method of claim 7 wherein the writing, reading and comparing occurs repeatedly to test the entire memory or to repeatedly test a same memory location to identify intermittent errors.

12. The method of claim 7 wherein the memory comprises DRAM, the machine executable instructions comprise micro-code, and the micro-code is executed by a state machine.

13. The method of claim 7 further comprising logging and storing the results of the comparison, or other analysis, of the written test data and the read test data to a pass/fail registers.

14. The method of claim 7 further comprising, in response to a memory fail status, taking protective action that includes one or more of the following: repair, masking, replacement, or removal from a memory map.

15. A memory test system comprising:
a controller configured to initiate testing of the memory;
a test pattern generator configured to generate test patterns though execution of micro-code;
a memory controller configured to write the generated test patterns to memory and read test patterns from memory as read test patterns; and
a comparator configured to compare the generated test pattern to the read test pattern to identify memory locations that result in memory errors.

16. The system of claim 15 wherein the test pattern generator is a processor or state machine executing the micro-code.

17. The system of claim 16 wherein the micro-code is written to a memory assessable by the processor and may be replaced with different micro-code by a user of the memory test system through an interface to thereby generate different test patterns.

18. The system of claim 15 further comprising registers configured to store the results of the comparing and memory addresses or tested memory locations.

19. The system of claim 15 wherein the controller is configured to introduce a delay between the writing of the generated test pattern and the reading of the read test pattern.

20. The system of claim 15 wherein the system further comprises a memory storing a non-transitory test pattern and the test pattern generator is configured retrieve the test pattern from the memory.
